(19) United States
(12) Patent Application Publication
(10) Pub. No.: US 2026/0255788 A1
(43) Pub. Date: Aug. 27, 2026

(54) TANDEM OLED STRUCTURE AND DISPLAY PANEL

(71) Applicants: Mianyang BOE Optoelectronics Technology Co., Ltd., Mianyang, Sichuan (CN); BOE Technology Group Co., Ltd., Beijing (CN)

(72) Inventors: Junlian LI, Beijing (CN); Guanghua XU, Beijing (CN); Taofeng XIE, Beijing (CN); Fan HE, Beijing (CN); Shihsyong HUANG, Beijing (CN); Xiaoxue WEN, Beijing (CN); Lei HE, Beijing (CN); Xinghao XUE, Beijing (CN)

(21) Appl. No.: 18/992,961

(22) PCT Filed: Aug. 12, 2024
(86) PCT No.: PCT/CN2024/111514

§ 371 Date: Jan. 9, 2025

(30) Foreign Application Priority Data
Sep. 22, 2023 (CN) 202311238796.X

(51) Int. Cl. H10K 50/19; H10K 59/122; H10K 59/80

(52) U.S. Cl. CPC H10K 50/19; H10K 59/122; H10K 59/80521

(57) ABSTRACT

The present application discloses a tandem OLED structure and a display panel. The tandem OLED structure includes a cathode layer, an anode layer, a plurality of light-emitting material layers, a charge generation layer, a hole barrier layer, and an isolation portion. The hole barrier layer is located on a side of the cathode layer close to the light-emitting material layers, and the hole barrier layer isolates the charge generation layer from the cathode layer in a first direction. The isolation portion is located at an edge of the charge generation layer, and the isolation portion isolates the charge generation layer from the cathode layer in a second direction. The first direction is parallel to a direction from the cathode layer to the anode layer, and the second direction is perpendicular to the direction from the cathode layer to the anode layer.

### CROSS-REFERENCE TO RELATED APPLICATIONS

This application is a US national stage of international PCT Application No. PCT/CN 2024/111514, filed on Aug. 12, 2024, which claims priority to Chinese patent application No. 202311238796X, filed with the Chinese Patent Office on Sep. 22, 2023, the entire contents of which are incorporated herein by reference for all purposes.

### TECHNICAL FIELD

The present application relates to the field of display devices, and in particular, to a tandem OLED structure and a display panel.

### BACKGROUND

With the development of display technology, people have higher and higher requirements for display quality of display devices. Compared with common OLED devices, tandem OLED devices have characteristics of long service life, narrow full width at half maximum (to achieve high color gamut), and low power consumption.

In tandem OLED devices, light-emitting material layers are connected via a charge generation layer (CGL). Under action of electric field, charge separation occurs in the CGL layer, and electrons and holes are transmitted to different light-emitting material layers respectively, achieving light-emitting efficiency several times that of a single stack OLED device under a same current density.

However, in the existing tandem OLEDs, holes generated in the CGL are affected by the electrons in the cathode layer, thereby affecting light-emitting efficiency of the light-emitting material layers.

### SUMMARY

The purpose of the present application is to provide a tandem OLED structure with relatively high light-emitting efficiency and a display panel.

The present application discloses a tandem OLED structure, which includes:
a cathode layer;
an anode layer;
a plurality of light-emitting material layers, where the plurality of light-emitting material layers are connected in series/tandem, and the plurality of light-emitting material layers are located between the cathode layer and the anode layer;
a charge generation layer, located between the plurality of light-emitting material layers, where projection of the light-emitting material layers in a first direction falls in the charge generation layer;
a hole barrier layer, located on a side of the cathode layer close to the light-emitting material layers, where the hole barrier layer isolates the charge generation layer from the cathode layer in a first direction; and
an isolation portion, located at an edge of the charge generation layer, where the isolation portion isolates the charge generation layer from the cathode layer in a second direction;
the first direction is parallel to a direction from the cathode layer to the anode layer, and the second direction is perpendicular to the direction from the cathode layer to the anode layer.

Optionally, the isolation portion includes a first isolation structure formed by an edge of the hole barrier layer extending.

Optionally, the tandem OLED structure further includes:
an electron transport layer, located between the hole barrier layer and the cathode layer; and
the isolation portion includes a second isolation structure formed by edges of the hole barrier layer and the electron transport layer extending together.

Optionally, the isolation portion includes a third isolation structure made of an insulating material.

Optionally, the tandem OLED structure further includes:
a substrate;
a first planarization layer, arranged between the substrate and the anode layer;
a pixel defining layer, located on a side of the first planarization layer away from the substrate; and
a hole transport layer, located on a side of the pixel defining layer close to the charge generation layer;
a projection of the hole transport layer in the first direction coincides with the charge generation layer, and a projection of the charge generation layer in the first direction falls in the pixel defining layer.

Optionally, the third isolation structure is arranged on a side of the pixel defining layer facing the charge generation layer.

Optionally, a side of the substrate close to the first planarization layer is provided with a first protrusion structure, the first planarization layer covers the first protrusion structure, and a projection of the first protrusion structure in the first direction is covered by a projection of the third isolation structure in the first direction.

Optionally, a side of the first planarization layer close to the pixel defining layer is provided with a second planarization layer, a side of the first planarization layer close to the second planarization layer is provided with a second protrusion structure, the second planarization layer covers the second protrusion structure, and a projection of the second protrusion structure in the first direction is covered by a projection of the third isolation structure in the first direction.

Optionally, the charge generation layer includes an electron extraction layer and an electron receiving layer, the electron extraction layer is located on a side close to the anode layer, and the electron receiving layer is located on a side close to the cathode layer.

Optionally, a material of the electron extraction layer includes an N-type doped organic layer, and the electron receiving layer includes a P-type doped organic layer.

Optionally, a distance between an outer edge of the isolation portion and an outer edge of the charge generation layer is greater than or equal to 5 μm.

The present application further discloses a display panel, which includes the tandem OLED structure as described above, where the display panel includes a display region and a peripheral region around the display region.

Optionally, in the peripheral region, a side of the pixel defining layer away from the substrate is in contact with the hole transport layer and the electron transport layer.

Optionally, in the peripheral region, a conductive layer is provided in a same layer as the anode layer, and the conductive layer is in contact with the cathode layer to transmit a signal to the cathode layer.

Optionally, a side of the cathode layer away from the substrate is provided with an encapsulation layer, a side of the encapsulation layer away from the cathode layer is provided with a touch electrode layer, the touch electrode layer is provided with touch electrodes, and both the display region and the peripheral region are provided with the touch electrodes.

Compared with the related art, in the present application, an isolation portion arranged isolates the charge generation layer and the cathode layer in the second direction, preventing holes generated by the charge generation layer and electrons generated by the cathode layer from being recombined and quenched to disrupt orderly arrangement and transport of electrons and holes inside the charge generation layer, and improving light-emitting efficiency of the light-emitting material layer.

It should be understood that the above general descriptions and the below detailed descriptions are merely exemplary and explanatory, and are not intended to limit the present disclosure.

### BRIEF DESCRIPTION OF DRAWINGS

The accompanying drawings, which are incorporated in and constitute a part of the present application, illustrate examples consistent with the present application and, together with the description to explain the principles of the application.

FIG. 1 is structural diagram of a display panel according to the present application.

FIG. 2 is a structural diagram of a tandem OLED structure according to an embodiment of the present application.

FIG. 3 is a structural diagram of a tandem OLED structure according to another embodiment of the present application.

FIG. 4 is a structural diagram of a tandem OLED structure according to another embodiment of the present application.

FIG. 5 is a structural diagram of a tandem OLED structure according to another embodiment of the present application.

FIG. 6 is a structural diagram of a tandem OLED structure according to another embodiment of the present application.

FIG. 7 is a structural diagram of a tandem OLED structure according to another embodiment of the present application.

FIG. 8 is a structural diagram of a tandem OLED structure according to another embodiment of the present application.

### DETAILED DESCRIPTION

Exemplary embodiments will be described in detail here, examples of which are illustrated in the accompanying drawings. When the following description relates to the accompanying drawings, unless specified otherwise, the same numerals in different drawings represent the same or similar elements. Implementations described in the following examples do not represent all implementations consistent with the present application. Rather, they are merely device examples consistent with some aspects of the present application as detailed in the appended claims.

The terms used in this application are merely for the purpose of describing specific embodiments, and are not intended to limit this application. Unless otherwise defined, the technical or scientific terms used in the present application shall have the usual meanings understood by those of ordinary skill in the field to which the present application belongs. It is to be understood that, “first”, “second” and similar terms used in the specification and the claims of this patent application do not indicate any sequence or importance, but are only used to distinguish different components. Similarly, “one”, “a”, and similar terms also do not indicate a quantity limitation, but indicates that there is at least one. The term “a plurality” indicates two or more, unless specifically defined otherwise. Unless otherwise stated, the terms such as “front”, “rear”, “lower”, and/or “upper” are for ease of description only and are not limited to a position or a spatial orientation. The terms such as “comprise”, “include”, or any variant thereof mean that an element or article preceded by “comprise” or “include” encompasses elements or articles and their equivalents listed after “comprise” or “include”, do not exclude the existence of other elements or articles. “Connected to” or “connected with” and similar terms are not limited to physical or mechanical connections, and can include electrical connections, whether direct or indirect.

The terms used in this application are merely for the purpose of describing specific embodiments, and are not intended to limit this application. Terms like “a”, “the” and “said” in their singular forms in the present application and the appended claims are also intended to include plurality, unless clearly indicated otherwise in the context. It should also be understood that, the term “and/or” used herein indicates and includes any or all possible combinations of one or more associated listed items.

In the related art, holes in the CGL are affected by the cathode layer, thereby affecting the light-emitting efficiency of the light-emitting material layers.

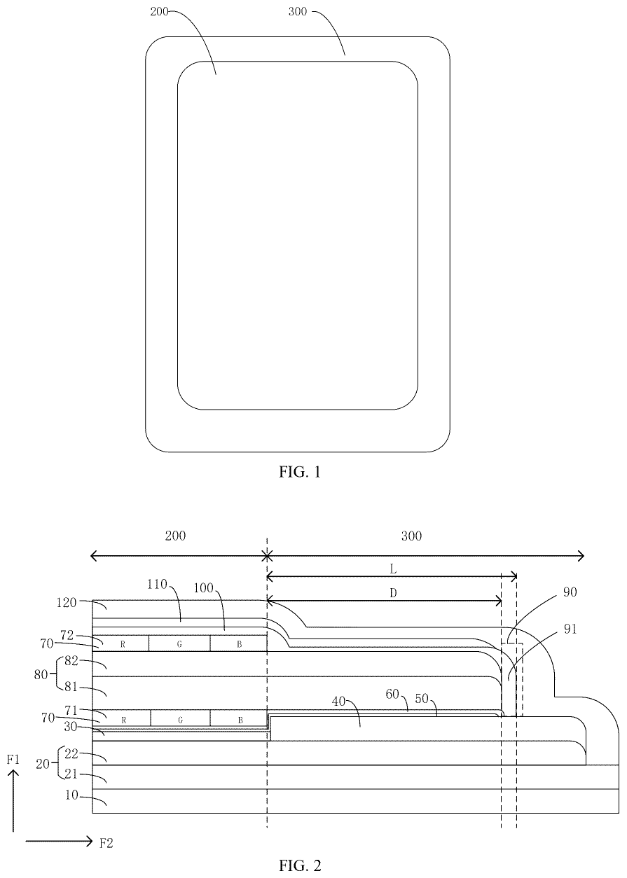

To solve the above technical problem, as illustrated in FIG. 2, the present application provides a tandem OLED structure, which includes:
a cathode layer 120;
an anode layer 30;
a plurality of light-emitting material layers 70, where the plurality of light-emitting material layers 70 are at different heights and in series/tandem, connection, and the plurality of light-emitting material layers 70 are located between the cathode layer 120 and the anode layer 30;
a charge generation layer 80, where the charge generation layer 80 is located between the plurality of light-emitting material layers 70, where projections of the light-emitting material layers 70 in a first direction falls in the charge generation layer 80;
a hole barrier layer 100, located on a side of the cathode layer 120 close to the light-emitting material layers 70, where the hole barrier layer 100 isolates the charge generation layer 80 from the cathode layer 120 in the first direction;
an isolation portion 90, where the isolation portion 90 is located at an edge of the charge generation layer 80, and the isolation portion 90 isolates the charge generation layer 80 from the cathode layer 120 in a second direction; and
the first direction F1 is parallel to a direction from the cathode layer 120 to the anode layer 30, and the second direction F2 is perpendicular to a direction from the cathode layer 120 to the anode layer 30.

To solve the above technical problem, the present application further provides a display panel, which includes the tandem OLED structure as described above.

In the present application, an isolation portion 90 arranged isolates the charge generation layer 80 from the cathode layer 120 in the second direction, preventing holes generated by the charge generation layer 80 and electrons generated by the cathode layer 120 from recombination and quenching and resultant disruption of orderly arrangement and transport of electrons and holes inside the charge generation layer 80. In this way, light-emitting efficiency of the light-emitting material layers is improved.

Various embodiments of the present application that are consistent with the above-mentioned creative concepts will be described in detail below.

As illustrated in FIG. 1 and FIG. 2, the display panel includes a display region 200 and a peripheral region 300 surrounding the display region 200. The present application discloses a tandem OLED structure that may be applied to an edge of the display region 200 and the peripheral region 300 of the display panel.

As illustrated in FIG. 2, in an optional embodiment, a portion of the tandem OLED structure located in the display region 200 of the present application includes a substrate 10. The substrate 10 may be a rigid substrate. For example, the rigid substrate may be a glass substrate or a Polymethyl methacrylate (PMMA) substrate, etc.

The substrate 10 may also be a flexible substrate. For example, the flexible substrate may be a polyethylene terephthalate (PET) substrate, a polyimide (PI) substrate, or a polyethylene naphthalate two formic acid glycol ester (PEN) substrate, etc. It may be understood that, the type of the substrate 10 includes a plurality of types, which may be selected and arranged according to actual needs, which is not limited in the embodiments of the present application.

A side of the substrate 10 is provided with a planarization layer 20. A driving circuit layer is provided between the substrate 10 and the planarization layer 20, and the structure of the driving circuit layer is not illustrated in the drawings. A plurality of pixel driving circuits are arranged in the driving circuit layer, and each pixel driving circuit is connected to a pixel for controlling the light emission of the pixel. The pixel driving circuit may include a plurality of thin-film transistors and a capacitor. For example, the pixel driving circuit may be a 2TIC, 3TIC, 5TIC, or 7TIC type pixel driving circuit. The specific structure of the driving circuit layer is arranged flexibly according to actual needs, which is not limited in the present application.

A side of the planarization layer 20 away from the substrate 10 is provided with a pixel defining layer 40. The pixel defining layer 40 is provided with a plurality of hollowed-out regions, and the pixel defining layer 40 defines positions of the pixels in the display panel through the hollowed-out regions. Each pixel in the display panel corresponds to a hollowed-out region of the pixel defining layer 40. A side of the planarization layer 20 away from the substrate 10 is provided with an anode layer 30, and the anode layer 30 is arranged on the planarization layer 20. At least a part of the projection of the anode layer 30 in the first direction F1 falls within the hollowed-out regions of the pixel defining layer 40. The sides of the pixel defining layer 40 and the anode layer 30 away from the planarization layer 20 are provided with a hole transport layer 50, and a side of the hole transport layer 50 away from the pixel defining layer 40 is provided with an electron barrier layer 60. A side of the electron barrier layer 60 away from the hole transport layer 50 is provided with a first light-emitting material layer 71. A side of the first light-emitting material layer 71 away from the electron barrier layer 60 is provided with a charge generation layer 80. A second light-emitting material layer 72 is arranged on the side of the charge generation layer 80 away from the first light-emitting material layer 71. A hole barrier layer 100 is arranged on the side of the second light-emitting material layer 72 away from the charge generation layer 80. A projection of the second light-emitting material layer 72 in the first direction coincides with the projection of the first light-emitting material layer 71 in the first direction. An electron transport layer 110 is arranged on the side of the hole barrier layer 100 away from the second light-emitting material layer 72. A cathode layer 120 is arranged on the side of the electron transport layer 110 away from the hole barrier layer 100. The first light-emitting material layer 71 includes a red light-emitting material R, a green light-emitting material G, and a blue light-emitting material B. The second light-emitting material layer 72 also includes a red light-emitting material R, a green light-emitting material G, and a blue light-emitting material B. The projection of the red light-emitting material R in the first light-emitting material layer 71 in the first direction coincides with the projection of the red light-emitting material R in the second light-emitting material layer 72 in the first direction; the projection of the green light-emitting material G in the first light-emitting material layer 71 in the first direction coincides with the projection of the green light-emitting material G in the second light-emitting material layer 72 in the first direction; the projection of the blue light-emitting material B in the first light-emitting material layer 71 in the first direction coincides with the projection of the blue light-emitting material B in the second light-emitting material layer 72 in the first direction. The projections of the first light-emitting material layer 71 and the second light-emitting material layer 72 in the first direction fall within the hollowed-out regions of the pixel defining layer 40. The first direction is a direction perpendicular to the charge generation layer 80, i.e., the direction F1 in the drawings.

When the tandem OLED structure emits light, the anode layer 30 transmits holes to the first light-emitting material layer 71 through the hole transport layer 50, and the charge generation layer 80 transmits electrons to the first light-emitting material layer 71. The electrons and holes meet in the first light-emitting material layer 71 to form excitons that excite the light-emitting molecules to emit visible light. The cathode layer 120 transmits electrons to the second light-emitting material layer 72 through the electron transport layer 110, and the charge generation layer 80 transmits holes to the second light-emitting material layer 72, the electrons and holes meet in the second light-emitting material layer 72 to form excitons that excite the light-emitting molecules to emit visible light. In this process, the electron barrier layer 60 traps electrons from the charge generation layer 80 in the first light-emitting material layer 71 to improve the light-emitting efficiency of the first light-emitting material layer 71. The hole barrier layer 100 traps the holes from the charge generation layer 80 in the second light-emitting material layer 72 to improve the light-emitting efficiency of the second light-emitting material layer 72.

The charge generation layer 80 may include an electron extraction layer 81 and an electron receiving layer 82. The materials of the electron extraction layer 81 and the electron reception layer 82 may be selected according to needs.

In an optional embodiment, the electron extraction layer 81 is a metal material, and the electron receiving layer 82 is a metal oxide. For example, the electron extraction layer 81 is made of lithium (Li) material, and the electron receiving layer 82 is made of molybdenum trioxide (MoO₃) material.

In an optional embodiment, the electron extraction layer 81 is an n-type doped organic material, and the electron receiving layer 82 is a p-type doped organic material. For example, the electron extraction layer 81 is made of Li-doped Alq3 (8-hydroxyquinoline aluminum) material, and the electron receiving layer 82 is made of HTA-CN material.

In an optional embodiment, the electron extraction layer 81 is an n-type doped organic material, and the electron receiving layer 82 is a p-type doped organic material For example, the electron extraction layer 81 is made of Alq3 (8-hydroxyquinoline aluminum) material doped with Mg, and the electron receiving layer 82 is made of m-MTDATA (3,3′,5,5′-tetramethyltriphenylamine) material doped with F₄-TCNQ (tetrafluoro-7,7,8,8-tetracyanoquinolinequinone). For another example, the electron extraction layer 81 is made of Li-doped Alq3 (8-hydroxyquinoline aluminum) material, and the electron receiving layer 82 is made of NPB (N,N′-di(1-naphthyl)-N,N′-diphenylaniline) material doped with FeCl₃.

The n-doped electron extraction layer 81 may generate electron-hole pairs. Since energy band bending occurs in the p-doped electron receiving layer 82, the holes of the electron extraction layer 81 may be transferred to the electron receiving layer 82. The electrons generated by the electron extraction layer 81 may, through the interface between the electron extraction layer 81 and the first light-emitting material layer 71, be transmitted to the first light-emitting material layer 71. The electron receiving layer 82 may receive the holes generated by the electron extraction layer 81 and transmit them to the second light-emitting material layer 72. Electrons from the electron transport layer 110 enter the electron receiving layer 82. The p-type doped electron receiving layer 82 may allow electrons to effectively tunnel to the n-type doped electron extraction layer 81, thereby reducing the hole injection barrier and achieving current multiplication.

In an optional embodiment, the electron extraction layer 81 and the electron receiving layer 82 are both made of non-doped materials.

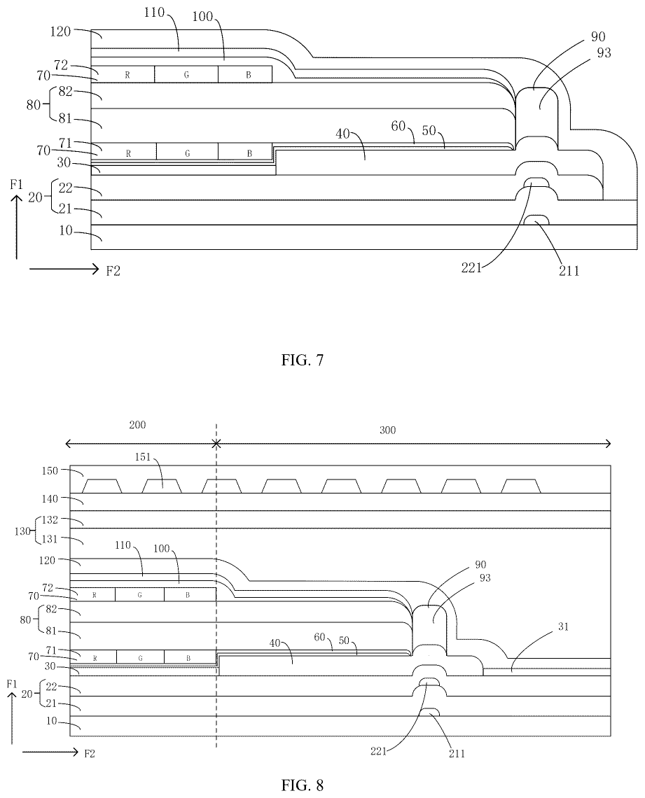

As illustrated in FIG. 2 to FIG. 7, a substrate 10, a planarization layer 20, a pixel defining layer 40, a hole transport layer 50, an electron barrier layer 60, an electron extraction layer 81, an electron receiving layer 82, a hole barrier layer 100, an electron transport layer 110, and a cathode layer 120 extend from the edge of the display region 200 into the peripheral region 300.

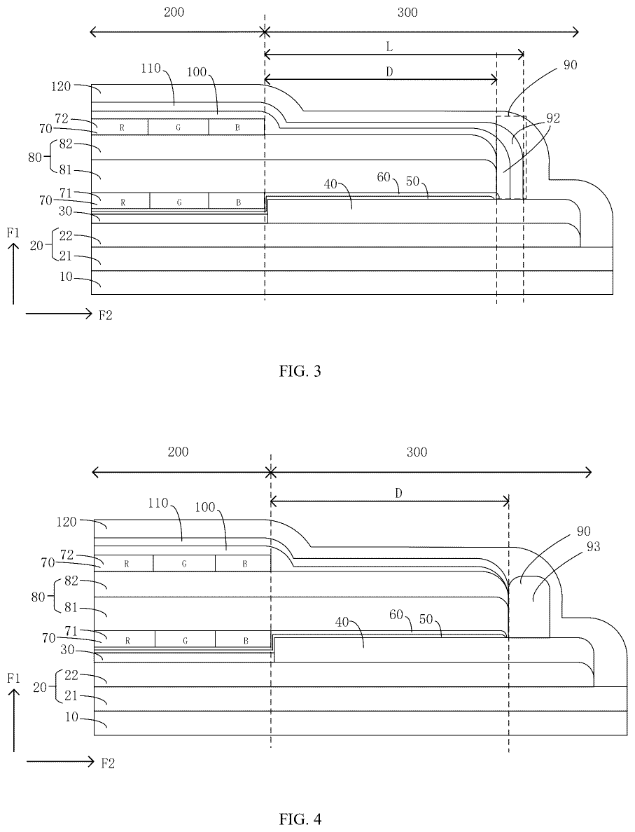

In an optional embodiment, as illustrated in FIG. 2, FIG. 3, and FIG. 4, the display panel is applied to a mobile phone device, which includes an upper side and a lower side that are opposite, a left side and a right side that are opposite and a plurality of outline corners. On the left and right sides and the upper side of the mobile phone, the distance D from the outer edges of the hole transport layer 50, the electron barrier layer 60, the electron extraction layer 81, the electron receiving layer 82, and the hole barrier layer 100 to the edge of the display region 200 is 75-105 μm, which may optionally be 75, 80, 90, 100, or 105 μm. On the lower side of the mobile phone, the distance D from the outer edges of the hole transport layer 50, the electron barrier layer 60, the electron extraction layer 81, the electron receiving layer 82, and the hole barrier layer 100 to the edge of the display region 200 is 85-115 μm, which may optionally be 85, 90, 100, 110, or 115 μm. At the outline corners of the mobile phone, the distance D from the outer edges of the hole transport layer 50, the electron barrier layer 60, the electron extraction layer 81, the electron receiving layer 82, and the hole barrier layer 100 to the edge of the display region 200 is 145-175 μm, which may optionally be 145, 150, 160, 170, or 175 μm. The projections of the hole transport layer 50, the electron barrier layer 60, the electron extraction layer 81, the electron receiving layer 82, the hole barrier layer 100, and the electron transport layer 110 in the first direction fall within the projections of the substrate 10, the planarization layer 20, the pixel defining layer 40, and the cathode layer 120 in the first direction. The edge of the cathode layer 120 bends towards the pixel defining layer 40 and wraps around the edges of the electron extraction layer 81 and electron receiving layer 82. The edges of the electron extraction layer 81 and electron receiving layer 82 away from the display region 200 are provided with an isolation portion 90, which isolates the charge generation layer 80 from the cathode layer 120 in the second direction, so that the charge generation layer 80 is not in contact with the cathode layer 120 in the second direction. The first direction is a direction perpendicular to the charge generation layer 80, i.e., the direction F1 in the drawings. The second direction is a direction parallel to the charge generation layer 80, i.e., the direction F2 in the drawings. With this structure, the charge generation layer 80 is isolated from the cathode layer 120 in the second direction, preventing holes generated by the charge generation layer 80 and electrons generated by the cathode layer 120 from being recombined and quenched to disrupt orderly arrangement and transport of electrons and holes inside the charge generation layer 80. The holes generated by the charge generation layer 80 are transmitted undisturbed to the second light-emitting material layer 72 close to the cathode layer 120, and the holes are recombined in the second light-emitting material layer 72 with the electrons from the cathode layer 120, effectively enabling the second light-emitting material layer 72 to emit light. The electrons generated by the charge generation layer 80 are transmitted undisturbed to the first light-emitting material layer 71 close to the anode layer 30, and the holes are recombined in the first light-emitting material layer 71 with the electrons from the anode layer 30, effectively enabling the first light-emitting material layer 71 to emit light.

As illustrated in FIG. 2, in an optional embodiment, the display panel is applied to a mobile phone device, which includes an upper side and a lower side that are opposite, a left side and a right side that are opposite and a plurality of outline corners. On the left and right sides and the upper side of the mobile phone, the distance D from the outer edges of the hole transport layer 50, the electron barrier layer 60, the electron extraction layer 81, and the electron receiving layer 82 to the edge of the display region 200 is 75-105 μm, which may optionally be 75, 80, 90, 100, or 105 μm. On the lower side of the mobile phone, the distance D from the outer edges of the hole transport layer 50, the electron barrier layer 60, the electron extraction layer 81, and the electron receiving layer 82 to the edge of the display region 200 is 85-115 μm, which may optionally be 85, 90, 100, 110, or 115 μm. At the outline corners of the mobile phone, the distance D from the outer edges of the hole transport layer 50, the electron barrier layer 60, the electron extraction layer 81 and the electron receiving layer 82 to the edge of the display region 200 is 145-175 μm, which may optionally be 145, 150, 160, 170, or 175 μm.

The edge of the hole barrier layer 100 extends outward, bends towards the side of the pixel defining layer 40, and contacts the pixel defining layer 40, to form the first isolation structure 91 (the portion in the dashed line box in FIG. 2, the dashed line is used for easy understanding only and does not represent any structure). The first isolation structure 91 is the isolation part 90 or a part of the isolation part 90. At this time, when manufacturing the hole barrier layer 100, on the left and right sides and the upper side of the mobile phone, the distance L from the outer edge of the hole barrier layer 100 to the edge of the display region 200 is set to be greater than or equal to 145 μm, which may optionally be 145 μm, 150 μm, 155 μm, 160 μm, or 165 μm, etc. On the lower side of the mobile phone, the distance L from the outer edge of the hole barrier layer 100 to the edge of the display region 200 is set to be greater than or equal to 155 μm, which may optionally be 155 μm, 160 μm, 165 μm, 170 μm, or 175 μm, etc. At the outline corners of the mobile phone, the distance L from the outer edge of the hole barrier layer 100 to the edge of the display region 200 is set to be greater than or equal to 240 μm, which may optionally be 240 μm, 245 μm, 250 μm, 255 μm, or 260 μm, etc. At this time, on the left and right sides and upper and lower sides of the mobile phone, the distance from the outer edge of the first isolation structure 91 to the outer edge of the charge generation layer 80 is greater than or equal to 5 μm, and at the outline corners of the mobile phone, the distance from the outer edge of the first isolation structure 91 to the outer edge of the charge generation layer 80 is greater than or equal to 8 μm. At this time, the first isolation structure 91 isolates the charge generation layer 80 from the cathode layer 120 in the second direction, so that the charge generation layer 80 is not in contact with the cathode layer 120 in the second direction. The hole barrier layer 100 and the electron transport layer 110 isolate the charge generation layer 80 from the cathode layer 120 in the first direction, so that the charge generation layer 80 is not in contact with the cathode layer 120 in the first direction. The first direction F1 is parallel to a direction from the cathode layer 120 to the anode layer 30, and the second direction F2 is perpendicular to a direction from the cathode layer 120 to the anode layer 30.

As illustrated in FIG. 3, in an optional embodiment, the display panel is applied to a mobile phone device, which includes an upper side and a lower side that are opposite, a left side and a right side that are opposite and a plurality of outline corners. On the left and right sides and the upper side of the mobile phone, the distance D from the outer edges of the hole transport layer 50, the electron barrier layer 60, the electron extraction layer 81, and the electron receiving layer 82 to the edge of the display region 200 is 75-105 μm, which may optionally be 75, 80, 90, 100, or 105 μm. On the lower side of the mobile phone, the distance D from the outer edges of the hole transport layer 50, the electron barrier layer 60, the electron extraction layer 81, and the electron receiving layer 82 to the edge of the display region 200 is 85-115 μm, which may optionally be 85, 90, 100, 110, or 115 μm. At the outline corners of the mobile phone, the distance D from the outer edges of the hole transport layer 50, the electron barrier layer 60, the electron extraction layer 81 and the electron receiving layer 82 to the edge of the display region 200 is 145-175 μm, which may optionally be 145, 150, 160, 170, or 175 μm. The edges of the hole barrier layer 100 and the electron transport layer 110 both extend outward, bend towards the side of the pixel defining layer 40, and contact the pixel defining layer 40, to form a second isolation structure 92 (the portion in the dashed line box in FIG. 3, the dashed line is used for easy understanding only and does not represent any structure). The second isolation structure 92 is the isolation part 90 or a part of the isolation part 90. At this time, when manufacturing the hole barrier layer 100 and the electron transport layer 110, on the left and right sides and the upper side of the mobile phone, the distance L from the outer edges of the hole barrier layer 100 to the edge of the display region 200 is set to be greater than or equal to 145 μm, which may optionally be 145 μm, 150 μm, 155 μm, 160 μm, or 165 μm, etc. On the lower side of the mobile phone, the distance L from the outer edge of the hole barrier layer 100 to the edge of the display region 200 is set to be greater than or equal to 155 μm, which may optionally be 155 μm, 160 μm, 165 μm, 170 μm, or 175 μm, etc. At the outline corners of the mobile phone, the distance L from the outer edge of the hole barrier layer 100 to the edge of the display region 200 is set to be greater than or equal to 240 μm, which may optionally be 240 μm, 245 μm, 250 μm, 255 μm, or 260 μm, etc. At this time, on the left and right sides and upper and lower sides of the mobile phone, the distance from the outer edge of the second isolation structure 92 to the outer edge of the charge generation layer 80 is greater than or equal to 5 μm, and at the outline corners of the mobile phone, the distance from the outer edge of the second isolation structure 92 to the outer edge of the charge generation layer 80 is greater than or equal to 8 μm. At this time, the second isolation structure 92 isolates the charge generation layer 80 from the cathode layer 120 in the second direction, so that the charge generation layer 80 is not in contact with the cathode layer 120 in the second direction. The hole barrier layer 100 and the electron transport layer 110 isolate the charge generation layer 80 from the cathode layer 120 in the first direction, so that the charge generation layer 80 is not in contact with the cathode layer 120 in the first direction. The first direction F1 is parallel to a direction from the cathode layer 120 to the anode layer 30, and the second direction F2 is perpendicular to the direction from the cathode layer 120 to the anode layer 30.

As illustrated in FIG. 4, in an optional embodiment, the isolation part 90 includes or is a third isolation structure 93 made of an insulating material. The third isolation structure 93 may be an independent film layer structure, which is not a part of the pixel defining layer 40, the hole transport layer 50, the electron barrier layer 60, the electron extraction layer 81, the electron receiving layer 82, hole barrier layer 100, or electron transport layer 110. The insulating materials used to make the third isolation structure 93 may be polyimide, acrylic resin, polyamide or phenolic resin, etc. In this embodiment, the third isolation structure 93 is made of polyimide. The third isolation structure 93 is arranged on a side of the pixel defining layer 40 close to the charge generation layer 80. The third isolation structure 93 surrounds the edge of the charge generation layer 80 to isolate the charge generation layer 80 from the cathode layer 120 in the second direction, so that the charge generation layer 80 is not in contact with the cathode layer 120 in the second direction. The hole barrier layer 100 and the electron transport layer 110 isolate the charge generation layer 80 from the cathode layer 120 in the first direction, so that the charge generation layer 80 is not in contact with the cathode layer 120 in the first direction. The cross-section of the third isolation structure 93 may be a rectangle, a triangle or other irregular shape, as long as it can isolate the charge generation layer 80 from the cathode layer 120 in the second direction. The first direction F1 is parallel to a direction from the cathode layer 120 to the anode layer 30, and the second direction F2 is perpendicular to the direction from the cathode layer 120 to the anode layer 30.

TABLE 1

| | | | AA~Open | |
|---|---|---|---|---|
| ITEM | AA~P/E | AA~Dam1 | (HTL/CGL/ETL) | ETL~CGL |
| L/R | 850 | 570 | 90/90/145 | 55 |
| Up | 650 | 370 | 90/90/145 | 55 |
| Down | 626 | 250 | 100/100/155 | 55 |
| Corner | 900@45° | 620 | 160/160/240 | 80 |

In an optional embodiment, as illustrated in the above table 1, FIG. 2, and FIG. 3, the fourth column in the table represents the distances from the outer edges of the hole transport layer 50, the charge generation layer 80, and the electron transport layer 110 to the edge of the display region 200. The fifth column of the table represents the distance from the outer edge of the electron transport layer 110 to the outer edge of the charge generation layer 80. The second, third, fourth, and fifth rows of the table respectively represent the left and right sides, upper side, lower side, and outline corners of the display panel. On the left and right sides and the upper side of the display panel, the distance from the outer edges of the hole transport layer 50 and the charge generation layer 80 to the edge of the display region 200 is 90 μm, the distance from the electron transport layer 110 to the edge of the display region 200 is 145 μm, and the distance from the electron transport layer 110 to the outer edge of the charge generation layer 80 is 55 μm. On the lower side of the display panel, the distance from the outer edges of the hole transport layer 50 and the charge generation layer 80 to the edge of the display region 200 is 100 μm, the distance from the electron transport layer 110 to the edge of the display region 200 is 155 μm, and the distance from the outer edge of the electron transport layer 110 to the outer edge of the charge generation layer 80 is 55 μm. At the outline corners of the display panel, the distance from the outer edges of the hole transport layer 50 and the charge generation layer 80 to the edge of the display region 200 is 160 μm, the distance from the electron transport layer 110 to the edge of the display region 200 is 240 μm, and the distance from the outer edge of the electron transport layer 110 to the outer edge of the charge generation layer 80 is 80 μm.

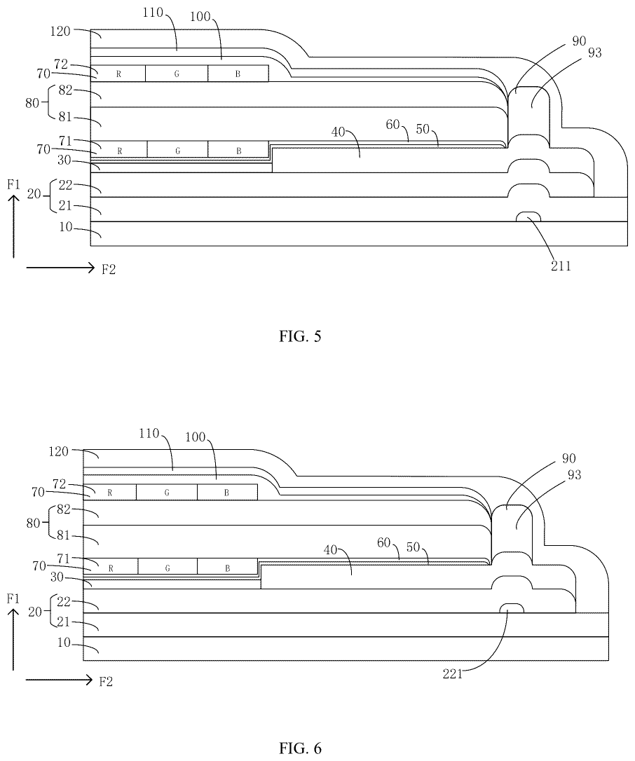

As illustrated in FIG. 5, in an optional embodiment, the planarization layer 20 includes a first planarization layer 21 arranged on a side of the substrate 10 close to the pixel defining layer 40, and a second planarization layer 22 arranged on a side of the first planarization layer 21 close to the pixel defining layer 40. The first planarization layer 21 and the second planarization layer 22 may be made of the same material or different materials. For example, the first planarization layer 21 may be a planarization layer formed from an inorganic material, and the second planarization layer 22 may be a planarization layer formed from an organic material; or the first planarization layer 21 may be a planarization layer formed from an organic material, and the second planarization layer 22 may be a planarization layer formed from an inorganic material; or both the first planarization layer 21 and the second planarization layer 22 may be planarization layers formed from inorganic materials; or both the first planarization layer 21 and the second planarization layer 22 may be planarization layers formed from organic materials. A thickness of the first planar layer 21 is substantially the same across, correspondingly, an upper surface of the first planarization layer 21 (the surface close to the second planarization layer 22) is a substantially flat surface. A thickness of the second planarization layer 22 is substantially the same across, correspondingly, an upper surface of the second planarization layer 22 (the surface close to the pixel defining layer 40 and the anode layer 30) is a substantially flat surface. Optionally, a side of the substrate 10 close to the first planarization layer 21 is provided with a first protrusion structure 211. The first protrusion structure 211 is conformally covered by the first planarization layer 21. The first protrusion structure 211 is arranged around the outer edge of the charge generation layer 80, and a projection of the first protrusion structure 211 in the first direction is covered by a projection of the third isolation structure 93 in the first direction. The first protrusion structure 211 may be a metal structure, or may be made of insulating materials such as polyimide. Arranging the first protrusion structure 211 may provide support for the third isolation structure 93 in the first direction, so that the third isolation structure 93 may better cover the outer edge of the charge generation layer 80 in the first direction, thereby enabling the third isolation structure 93 to better isolate the charge generation layer 80 from the cathode layer 120 in the second direction. The first direction F1 is parallel to a direction from the cathode layer 120 to the anode layer 30, and the second direction F2 is perpendicular to the direction from the cathode layer 120 to the anode layer 30.

As illustrated in FIG. 6, optionally, a side of the first planarization layer 21 close to the second planarization layer 22 is provided with a second protrusion structure 221. The second protrusion structure 221 is conformally covered by the second planarization layer 22. The second protrusion structure 221 is arranged around the outer edge of the charge generation layer 80, and a projection of the second protrusion structure 221 in the first direction is covered by a projection of the third isolation structure 93 in the first direction. The second protrusion structure 221 may be a metal structure, or may be made of insulating materials such as polyimide. Arranging the second protrusion structure 221 may provide support for the third isolation structure 93 in the first direction, so that the third isolation structure 93 may better cover the outer edge of the charge generation layer 80 in the first direction, thereby enabling the third isolation structure 93 to better isolate the charge generation layer 80 from the cathode layer 120 in the second direction.

As illustrated in FIG. 5 to FIG. 7, optionally, in the tandem OLED structure of the present application, the first protrusion structure 211 and the second protrusion structure 221 may be selectively arranged according to the actual situation. For example, only the first protrusion structure 211 or the second protrusion structure 221 may be provided; both the first protrusion structure 211 and the second protrusion structure 221 may alternatively be provided at the same time; or neither may be provided.

In the present application, the isolation portion 90 is provided to isolate the charge generation layer 80 from the cathode layer 120 in the second direction, the isolation portion 90 is located in the peripheral region 300, and the isolation portion 90 surrounds the display region 200, so that the charge generation layer 80 at the edge of the display region 200 is isolated from the cathode layer 120 in the second direction, the charge generation layer 80 at the edge of the display region 200 is isolated from the cathode layer 120 in the first direction by the hole barrier layer 100, and the charge generation layer 80 at the edge of the display region 200 is isolated from the anode layer 30 in the first direction by the electron barrier layer 60. Such arrangement may effectively prevent the holes generated by the charge generation layer 80 and the electrons generated by the cathode layer 120 from being recombined and quenched, and at the same time prevent the electrons generated by the charge generation layer 80 and the holes generated by the anode layer 30 from being recombined and quenched. It ensures the orderly arrangement and transmission of electrons and holes inside the charge generation layer 80, so that the holes generated by the charge generation layer 80 are transmitted undisturbed to the second light-emitting material layer 72 close to the cathode layer 120, and the holes are recombined with the electrons from the cathode layer 120 in the second light-emitting material layer 72, enabling the second light-emitting material layer 72 to emit light efficiently. The electrons generated by the charge generation layer 80 may be transmitted undisturbed to the first light-emitting material layer 71 close to the anode layer 30, and the holes are recombined with the electrons from the anode layer 30 in the first light-emitting material layer 71, enabling the first light-emitting material layer 71 to emit light efficiently. The light-emitting efficiency of the light-emitting material layers is improved.

The present application further provides a display panel, which includes the tandem OLED structure as described above.

As illustrated in FIG. 1 and FIG. 8, the display panel includes a display region 200 and a peripheral region 300 surrounding the display region 200. In the peripheral region 300, a side of the pixel defining layer 40 away from the substrate 10 is in contact with the hole transport layer 50. In the peripheral region 300, a conductive layer 31 is provided in the same layer as the anode layer 30, and the conductive layer 31 is in contact with the cathode layer 120 to transmit a signal to the cathode layer 120. A side of the cathode layer 120 away from the substrate 10 is provided with an encapsulation layer 130. The encapsulation layer 130 includes a first encapsulation layer 131 and a second encapsulation layer 132. The first encapsulation layer 131 may be an organic encapsulation layer or an inorganic encapsulation layer, and the second encapsulation layer 132 may be an organic encapsulation layer or an inorganic encapsulation layer. A side of the encapsulation layer 130 away from the cathode layer 120 is provided with a buffer layer 140. A side of the buffer layer away from the encapsulation layer 130 is provided with a touch electrode layer 150, and a plurality of touch electrodes 151 are provided in the touch electrode layer 150. Both the display region 200 and the peripheral region 300 are provided with the touch electrodes 151.

Those skilled in the art can think of other implementations of the present specification after considering the specification and practice of the present disclosure herein. The present application is intended to cover any variations, uses, modification or adaptations of the present application that follow the general principles of the present specification and include common knowledge or conventional technical methods in the related art that are not disclosed in the present application. The specification and implementations are considered as examples only, and true scope and spirit of the present application is indicated by the following claims.

It should be understood that the present application is not limited to the precise structure described above and shown in the accompanying drawings, and various modifications and changes can be made without departing from the scope of the present specification. The scope of the present application is limited only by the appended claims.

The above are the preferred examples of the present application, which are not intended to limit the application. Any modification, equivalent substitution, or improvement made within the spirit and principle of the present application shall be included within the protection scope of the application.

1. A tandem OLED structure, comprising:
a cathode layer;
an anode layer;
a plurality of light-emitting material layers, wherein the plurality of light-emitting material layers are connected in tandem, and the plurality of light-emitting material layers are located between the cathode layer and the anode layer;
a charge generation layer, located between the plurality of light-emitting material layers, wherein orthographic projections of the plurality of light-emitting material layers in a first direction fall in the charge generation layer;
a hole barrier layer, located on a side of the cathode layer close to the plurality of light-emitting material layers, wherein the hole barrier layer isolates the charge generation layer from the cathode layer in a first direction; and
an isolation portion, located at an edge of the charge generation layer, wherein the isolation portion isolates the charge generation layer from the cathode layer in a second direction;
wherein the first direction is parallel to a direction from the cathode layer to the anode layer, and the second direction is perpendicular to the direction from the cathode layer to the anode layer.

2. The tandem OLED structure according to claim 1, wherein the isolation portion comprises a first isolation structure formed by an edge of the hole barrier layer extending.

3. The tandem OLED structure according to claim 1, further comprising:
an electron transport layer, located between the hole barrier layer and the cathode layer;
wherein the isolation portion comprises a second isolation structure formed by edges of the hole barrier layer and the electron transport layer extending together.

4. The tandem OLED structure according to claim 1, wherein the isolation portion comprises a third isolation structure made of an insulating material.

5. The tandem OLED structure according to claim 4, further comprising:
a substrate;
a first planarization layer, arranged between the substrate and the anode layer;
a pixel defining layer, located on a side of the first planarization layer away from the substrate; and
a hole transport layer, located on a side of the pixel defining layer close to the charge generation layer;
wherein an orthographic projection of the hole transport layer in the first direction coincides with the charge generation layer, and an orthographic projection of the charge generation layer in the first direction falls in the pixel defining layer.

6. The tandem OLED structure according to claim 5, wherein the third isolation structure is arranged on a side of the pixel defining layer facing the charge generation layer.

7. The tandem OLED structure according to claim 6, wherein a side of the substrate close to the first planarization layer is provided with a first protrusion structure, the first planarization layer covers the first protrusion structure, and an orthographic projection of the first protrusion structure in the first direction is covered by an orthographic projection of the third isolation structure in the first direction.

8. The tandem OLED structure according to claim 6, wherein a side of the first planarization layer close to the pixel defining layer is provided with a second planarization layer, a side of the first planarization layer close to the second planarization layer is provided with a second protrusion structure, the second planarization layer covers the second protrusion structure, and an orthographic projection of the second protrusion structure in the first direction is covered by an orthographic projection of the third isolation structure in the first direction.

9. The tandem OLED structure according to claim 1, wherein the charge generation layer comprises an electron extraction layer and an electron receiving layer, the electron extraction layer is located on a side close to the anode layer, and the electron receiving layer is located on a side close to the cathode layer.

10. The tandem OLED structure according to claim 9, wherein a material of the electron extraction layer comprises an N-type doped organic layer, and the electron receiving layer comprises a P-type doped organic layer.

11. The tandem OLED structure according to claim 1, wherein a distance between an outer edge of the isolation portion and an outer edge of the charge generation layer is greater than or equal to 5 μm.

12. A display panel, comprising a tandem OLED structure, wherein the display panel comprises a display region and a peripheral region around the display region; and the tandem OLED structure comprises:
a cathode layer;
an anode layer;
a plurality of light-emitting material layers, wherein the plurality of light-emitting material layers are connected in tandem, and the plurality of light-emitting material layers are located between the cathode layer and the anode layer;
a charge generation layer, located between the plurality of light-emitting material layers, wherein orthographic projections of the plurality of light-emitting material layers in a first direction fall in the charge generation layer;
a hole barrier layer, located on a side of the cathode layer close to the plurality of light-emitting material layers, wherein the hole barrier layer isolates the charge generation layer from the cathode layer in a first direction; and
an isolation portion, located at an edge of the charge generation layer, wherein the isolation portion isolates the charge generation layer from the cathode layer in a second direction;
wherein the first direction is parallel to a direction from the cathode layer to the anode layer, and the second direction is perpendicular to the direction from the cathode layer to the anode layer.

13. (canceled)

14. The display panel according to claim 12, wherein in the peripheral region, a conductive layer is provided in a same layer as the anode layer, and the conductive layer is in contact with the cathode layer to transmit a signal to the cathode layer.

15. The display panel according to claim 12, wherein a side of the cathode layer away from the substrate is provided with an encapsulation layer, a side of the encapsulation layer away from the encapsulation layer is provided with a touch electrode layer, the touch electrode layer is provided with touch electrodes, and both the display region and the peripheral region are provided with the touch electrodes.

16. The display panel according to claim 12, wherein the isolation portion comprises a first isolation structure formed by an edge of the hole barrier layer extending.

17. The display panel according to claim 12, wherein the tandem OLED structure further comprises an electron transport layer, located between the hole barrier layer and the cathode layer;
wherein the isolation portion comprises a second isolation structure formed by edges of the hole barrier layer and the electron transport layer extending together.

18. The display panel according to claim 12, wherein the isolation portion comprises a third isolation structure made of an insulating material.

19. The display panel according to claim 18, further comprising:
a substrate;
a first planarization layer, arranged between the substrate and the anode layer;
a pixel defining layer, located on a side of the first planarization layer away from the substrate; and
a hole transport layer, located on a side of the pixel defining layer close to the charge generation layer;
wherein an orthographic projection of the hole transport layer in the first direction coincides with the charge generation layer, and an orthographic projection of the charge generation layer in the first direction falls in the pixel defining layer.

20. The display panel according to claim 19, wherein the third isolation structure is arranged on a side of the pixel defining layer facing the charge generation layer.

21. The tandem OLED structure according to claim 4, wherein the third isolation structure is independent from the hole barrier layer.
